(19) United States
(12) Patent Application Publication
(10) Pub. No.: US 2024/0305060 A1
(43) Pub. Date: Sep. 12, 2024

(54) SEMICONDUCTOR LASER MODULE AND LASER MACHINING APPARATUS

(71) Applicant: Mitsubishi Electric Corporation, Chiyoda-ku, Tokyo (JP)

(72) Inventors: Yuki OKAMOTO, Tokyo (JP); Daisuke MORITA, Tokyo (JP)

(73) Assignee: Mitsubishi Electric Corporation, Chiyoda-ku, Tokyo (JP)

(21) Appl. No.: 18/573,656

(22) PCT Filed: Aug. 29, 2022
(86) PCT No.: PCT/JP2022/032379

§ 371 Date: Dec. 22, 2023

(30) Foreign Application Priority Data
Aug. 30, 2021 (JP) 2021-139993

(51) Int. Cl. H01S 5/024; B23K 26/06; H01S 5/02251; H01S 5/023; H01S 5/042; H01S 5/40

(52) U.S. Cl. CPC H01S 5/02423; B23K 26/0608; H01S 5/02251; H01S 5/023; H01S 5/02469; H01S 5/04256; H01S 5/4012

(57) ABSTRACT

A semiconductor laser module includes: a manifold having a water passage through which cooling water can flow, the water passage being provided inside the manifold; a heat sink disposed on the manifold; a first electrode disposed in a first region of the heat sink; an insulating layer disposed on the first electrode; a submount disposed in a second region of the heat sink, a laser diode element disposed on the submount, the laser diode element emitting a laser beam; a feed structure disposed on the laser diode element; and a second electrode provided on the insulating layer and the feed structure such that the second electrode is in contact with the insulating layer and the feed structure. The water passage has a curved portion in the manifold, the curved portion including a continuous curved surface with no corner portion.

### FIELD

The present disclosure relates to a semiconductor laser module that outputs a laser beam, and a laser machining apparatus.

### BACKGROUND

A high-output laser device typified by a light source for a laser machining apparatus obtains high output light by optically coupling oscillation light from a plurality of semiconductor laser modules. In order to obtain a further output, either the number of semiconductor laser modules or the output of each single semiconductor laser module is increased. When the number of semiconductor laser modules is increased, the laser device increases in size. Thus, it is desirable to increase the output of each single semiconductor laser module. An increase in output of the semiconductor laser module is accompanied by an increase in the amount of heat generation. This leads to a problem with output characteristics and long-term reliability due to an increase in driving temperature for a laser diode element. Therefore, a structure of a semiconductor laser module has been developed in such a way as to achieve high heat discharge performance.

Patent Literature 1 discloses a semiconductor laser module with cooling efficiency enhanced not only for a lower surface side but also for an upper surface side of a laser diode element. The semiconductor laser module described in Patent Literature 1 includes a manifold, a heat sink, a first electrode, and a second electrode. The heat sink is provided in contact with an upper surface of the manifold. The first electrode is provided on a part of an upper surface of the heat sink. The second electrode is provided on an upper surface of the first electrode via an insulating layer in such a way as to face the heat sink. The insulating layer can transfer heat to the first electrode. In addition, the semiconductor laser module described in Patent Literature 1 includes a submount and a laser diode element. The submount is provided on another part of the upper surface of the heat sink where the first electrode is not disposed, and is electrically connected to the first electrode. The laser diode element is provided on an upper surface of the submount. An upper surface of the laser diode element is electrically connected to the second electrode. In the semiconductor laser module described in Patent Literature 1, a first flow path and a second flow path, which is different from the first flow path, are provided. The first flow path is for circulating cooling water below a region of the heat sink where the laser diode element is disposed. The second flow path is for circulating cooling water below a region of the manifold where the first electrode is disposed.

With such a configuration, heat generated by the laser diode element is discharged by cooling water flowing through the first flow path via the submount and the heat sink, and is also discharged by cooling water flowing through the second flow path via the second electrode, the insulating layer, the first electrode, the heat sink, and the manifold.

### CITATION LIST

### Patent Literature

Patent Literature 1: WO 2019/009172 A

### SUMMARY OF INVENTION

### Problem to be Solved by the Invention

However, in the technique described in Patent Literature 1, directions of the first flow path and the second flow path are changed at right angles inside the manifold. It is known that pressure loss increases when there is a corner portion bent at a right angle in the flow path. Therefore, there has been a demand for reduction of pressure loss in the flow path.

The present disclosure has been made in view of the above, and an object of the present disclosure is to obtain a semiconductor laser module capable of reducing pressure loss of cooling water flowing inside a manifold as compared with the conventional technique.

### Means to Solve the Problem

In order to solve the above-described problem and achieve the object, a semiconductor laser module according to the present disclosure includes a manifold, a heat sink, a first electrode, an insulating layer, a submount, a laser diode element, a feed structure, and a second electrode. The manifold has a water passage through which cooling water can flow, the water passage being provided inside the manifold. The heat sink is disposed on the manifold, and allows the cooling water to circulate through the water passage of the manifold and the heat sink. The first electrode is disposed in a first region of the heat sink. The insulating layer is disposed on the first electrode. The submount is disposed in a second region of the heat sink, which is different from the first region, and is electrically and thermally conductive. The laser diode element is disposed on the submount, and emits a laser beam. The feed structure is disposed on the laser diode element, and is electrically and thermally conductive. The second electrode is provided on the insulating layer and the feed structure such that the second electrode is in contact with the insulating layer and the feed structure. The water passage has a curved portion in the manifold, the curved portion including a continuous curved surface with no corner portion.

### Effects of the Invention

The semiconductor laser module according to the present disclosure has the effect of enabling pressure loss of cooling water flowing inside the manifold to be reduced as compared with the conventional technique.

### BRIEF DESCRIPTION OF DRAWINGS

FIG. 1 is a perspective view of a semiconductor laser module according to a first embodiment, which schematically shows an example of a configuration of the semiconductor laser module.

FIG. 2 is a partial cross-sectional view of the semiconductor laser module according to the first embodiment, which schematically shows the example of the configuration of the semiconductor laser module.

FIG. 3 is a front view of the semiconductor laser module according to the first embodiment, which schematically shows the example of the configuration of the semiconductor laser module.

FIG. 4 is a top view of a manifold of the semiconductor laser module according to the first embodiment, which schematically shows an example of a configuration of the manifold.

FIG. 5 is a cross-sectional view of the manifold of the semiconductor laser module according to the first embodiment, which schematically shows the example of the configuration of the manifold, and is a cross-sectional view taken along line V-V of FIG. 4.

FIG. 6 is a diagram schematically showing an example of a method for manufacturing the manifold to be used in the semiconductor laser module according to the first embodiment.

FIG. 7 is a cross-sectional view of manifolds of semiconductor laser modules of the first embodiment and a conventional example, which schematically illustrates configurations of water passages in the manifolds.

FIG. 8 is a side view of a manifold of a semiconductor laser module according to a second embodiment, which schematically shows an example of a configuration of the manifold.

FIG. 9 is a cross-sectional view of the manifold of the semiconductor laser module according to the second embodiment, which schematically shows the example of the configuration of the manifold, and is a cross-sectional view taken along line IX-IX of FIG. 8.

FIG. 10 is a diagram schematically showing an example of a method for manufacturing the manifold to be used in the semiconductor laser module according to the second embodiment.

FIG. 11 is a cross-sectional view of the manifold of the semiconductor laser module, which shows a conventional example of a water passage in the manifold.

FIG. 12 is a top view of a manifold of a semiconductor laser module according to a third embodiment, which schematically shows an example of a configuration of the manifold.

FIG. 13 is a cross-sectional view of the manifold of the semiconductor laser module according to the third embodiment, which schematically shows the example of the configuration of the manifold, and is a cross-sectional view taken along line XIII-XIII of FIG. 12.

FIG. 14 is a cross-sectional view of the manifold of the semiconductor laser module, which shows a conventional example of a water passage in the manifold.

FIG. 15 is a diagram schematically showing an example of a configuration of a laser machining apparatus according to a fourth embodiment.

FIG. 16 is a diagram schematically showing an example of a configuration of a laser oscillator to be used in the laser machining apparatus according to the fourth embodiment.

### DESCRIPTION OF EMBODIMENTS

Hereinafter, a semiconductor laser module and a laser machining apparatus according to embodiments of the present disclosure will be described in detail with reference to the drawings.

### First Embodiment

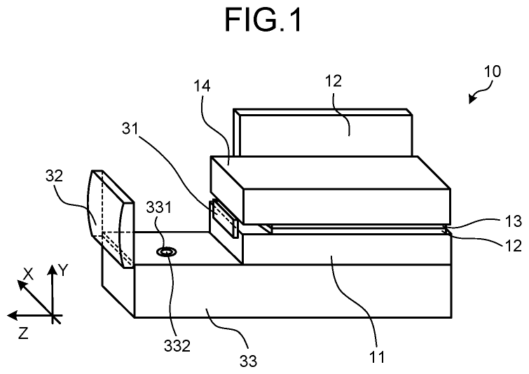

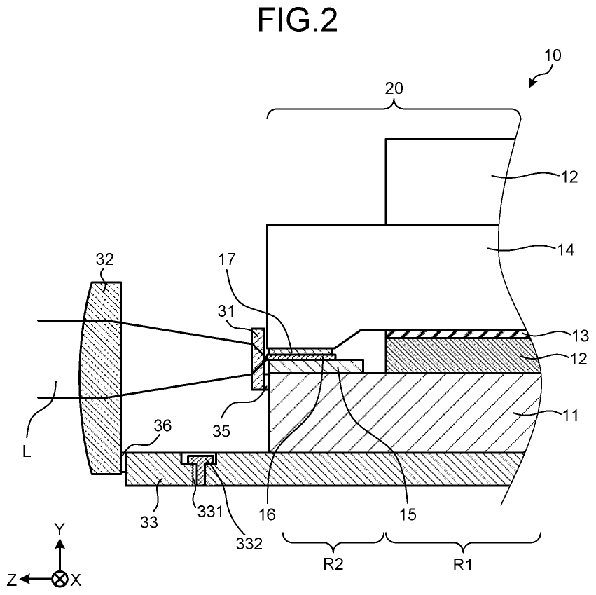

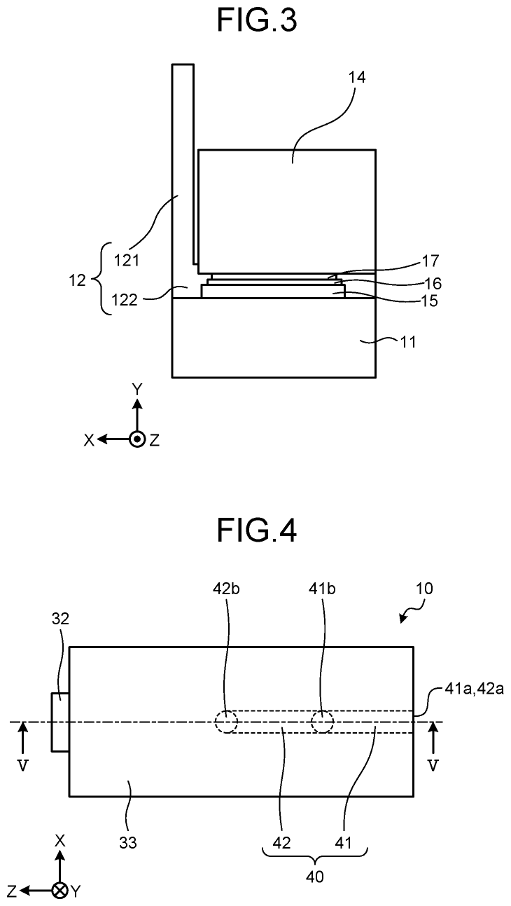

FIG. 1 is a perspective view of a semiconductor laser module according to a first embodiment, which schematically shows an example of a configuration of the semiconductor laser module. FIG. 2 is a partial cross-sectional view of the semiconductor laser module according to the first embodiment, which schematically shows the example of the configuration of the semiconductor laser module. FIG. 3 is a front view of the semiconductor laser module according to the first embodiment, which schematically shows the example of the configuration of the semiconductor laser module. Hereinafter, a Z-axis direction is defined as a direction in which a laser beam L is emitted, a Y-axis direction is defined as a direction perpendicular to the Z-axis and a direction in which members included in a semiconductor laser module 10 are stacked, and an X-axis direction is defined as a direction perpendicular to both the Z-axis and the Y-axis. Furthermore, a relationship between relative positions of two objects in the Y-axis direction is represented as upper and lower. In addition, a plane perpendicular to the Z-axis direction on which a laser diode element 16 is provided is defined as a front face. A relationship between relative positions of two objects in the Z-axis direction is represented as front and rear. FIG. 2 corresponds to a YZ cross section of FIG. 1. In addition, FIG. 3 illustrates a front view of the semiconductor laser module from which a fast axis collimator (FAC) 31 and a slow axis collimator (SAC) 32 have been removed.

The semiconductor laser module 10 includes a heat sink 11, an anode electrode 12, an insulating sheet 13, a cathode electrode 14, a submount 15, the laser diode element 16, and a feed structure 17.

The heat sink 11 is a heat dissipation member for preventing the laser diode element 16 from increasing in temperature. The heat sink 11 is a member that is disposed on a manifold 33 to be described below and can circulate cooling water through the heat sink 11 and a water passage of the manifold 33. The heat sink 11 has a tabular or rectangular parallelepiped structure extending in the Z-axis direction. The heat sink 11 is made of a material having good thermal conductivity. Here, the heat sink 11 is made of a material also having electrical conductivity. In one example, the heat sink 11 is desirably made of copper (Cu). In addition, a water passage through which cooling water flows is provided inside the heat sink 11. An upper surface of the heat sink 11 has an electrode placement region R1 and an element placement region R2. The electrode placement region R1 corresponds to a first region. The element placement region R2 corresponds to a second region.

The anode electrode 12 having an L-shape in an XY plane is disposed in the electrode placement region R1 of the heat sink 11. In one example, the anode electrode 12 is fixed to the electrode placement region R1 of the heat sink 11 with an adhesive (not illustrated). A conductive adhesive is used as the adhesive so as to maintain electrical connection between the anode electrode 12 and the heat sink 11. The anode electrode 12 includes an L-shaped member having a first portion 121 and a second portion 122. The first portion 121 is a tabular portion parallel to a YZ plane. The second portion 122 is a tabular portion parallel to a ZX plane. The anode electrode 12 is an electrode that is connected to a power supply (not illustrated) and supplies current to the laser diode element 16. The anode electrode 12 is connected to a p-type semiconductor side of the laser diode element 16. The anode electrode 12 and the heat sink 11 are electrically connected. An example of the anode electrode 12 is copper. In one example, the anode electrode 12 corresponds to a first electrode.

The cathode electrode 14 is disposed on the second portion 122 of the anode electrode 12 via the insulating sheet 13. The cathode electrode 14 and the heat sink 11 are substantially identical in shape and size in the ZX plane. In other words, the cathode electrode 14 has a structure projecting forward, that is, projecting in the positive direction of the Z-axis, with respect to the second portion 122 of the anode electrode 12 on the ZX plane. In the X-axis direction, the cathode electrode 14 is disposed at a distance from the first portion 121 of the anode electrode 12 so that the cathode electrode 14 does not come into contact with the first portion 121 of the anode electrode 12. The cathode electrode 14 is an electrode that is connected to the power supply (not illustrated) and supplies current to the laser diode element 16. The cathode electrode 14 is connected to an n-type semiconductor side of the laser diode element 16. The cathode electrode 14 also has a function of dissipating heat generated by the laser diode element 16. An example of the cathode electrode 14 is copper. In one example, the cathode electrode 14 corresponds to a second electrode.

The insulating sheet 13 is an insulating layer disposed on the second portion 122 of the anode electrode 12 and provided so as to insulate the anode electrode 12 and the cathode electrode 14 from each other. In one example, the insulating sheet 13 is smaller in size than the second portion 122 of the anode electrode 12. The insulating sheet 13 is disposed on the second portion 122 such that the insulating sheet 13 does not extend beyond the second portion 122. The second portion 122 is bonded to the insulating sheet 13, and the insulating sheet 13 is bonded to the cathode electrode 14, with an adhesive (not illustrated). An insulating adhesive having no electrical conductivity is used as the adhesive so as to electrically insulate the anode electrode 12 and the cathode electrode 14 from each other.

The laser diode element 16 is disposed in the element placement region R2 of the heat sink 11 via the submount 15. The submount 15 is fixed on the element placement region R2 of the heat sink 11. In one example, the submount 15 is fixed to the heat sink 11 with a conductive adhesive (not illustrated). The submount 15 is an intermediate member for alleviating stress generated in the laser diode element 16 due to a difference in linear expansion coefficient between the heat sink 11 and the laser diode element 16. That is, the submount 15 desirably has a linear expansion coefficient between a linear expansion coefficient of the laser diode element 16 and a linear expansion coefficient of the heat sink 11. In addition, the submount 15 is thermally conductive so as to transfer heat from the laser diode element 16 to the heat sink 11, and is also electrically conductive so as to obtain electrical connection with the anode electrode 12 via the heat sink 11. Examples of a material for the submount 15 include copper tungsten (CuW) and aluminum nitride (AlN).

The laser diode element 16 is disposed and fixed on the submount 15. The laser diode element 16 is an end surface-emitting laser that has a p-n junction in which a p-type semiconductor layer and an n-type semiconductor layer are stacked in the Y-axis direction and emits the laser beam L in the Z-axis direction. As an example, gallium arsenide (GaAs) is used as a base material of the laser diode element 16, and indium gallium arsenide (InGaAs) is used as an active layer of the laser diode element 16. In the Z-axis direction, the laser diode element 16 is disposed such that a front end surface of the laser diode element 16 is substantially aligned with front end surfaces of the heat sink 11 and the cathode electrode 14.

The feed structure 17 that is electrically and thermally conductive is disposed on the laser diode element 16. The feed structure 17 electrically connects the laser diode element 16 and the cathode electrode 14, and an area of contact between the feed structure 17 and the laser diode element 16 is sufficiently large. As a result, the feed structure 17 has a function of improving the amount of heat dissipation from an upper surface of the laser diode element 16.

A space above the element placement region R2 of the heat sink 11 is covered with the cathode electrode 14. The submount 15, the laser diode element 16, and the feed structure 17 are disposed in the space between the heat sink 11 and the cathode electrode 14.

The anode electrode 12 is electrically connected to the laser diode element 16 via the heat sink 11 and the submount 15. The cathode electrode 14 is electrically connected to the laser diode element 16 via the feed structure 17.

Note that the case where the heat sink 11 is electrically conductive has been described above, but an insulating layer may be partially included in the heat sink 11. In this case, an upper portion of the heat sink 11 just needs to be made of an electrically conductive material. Alternatively, an electrically conductive material just needs to be provided between the heat sink 11 and the anode electrode 12 and between the heat sink 11 and the submount 15.

A structure that includes the heat sink 11, the anode electrode 12, the insulating sheet 13, the cathode electrode 14, the submount 15, the laser diode element 16, and the feed structure 17, and emits the laser beam L is hereinafter referred to as a laser emission unit 20.

In addition, the semiconductor laser module 10 includes the FAC 31, the SAC 32, and the manifold 33.

The FAC 31 is an optical component that is provided on a Z-axis-direction end surface of the laser diode element 16 of the laser emission unit 20 and collimates a fast-axis direction component of the laser beam L emitted from the laser diode element 16. In one example, the FAC 31 is fixed to a Z-axis-direction end surface of the heat sink 11 with an adhesive 35. With reference to the shape, diameter, and the like of the laser beam L emitted from the laser diode element 16, a position of the FAC 31 is adjusted both in the Y-axis direction and in the Z-axis direction, and an angle of rotation of the FAC 31 around the Z-axis is adjusted. Then, the FAC 31 is fixed to the end surface of the heat sink 11 with the adhesive 35 such that the FAC 31 is disposed at the position adjusted both in the Y-axis direction and in the Z-axis direction, and that the adjusted angle of rotation around the Z-axis is achieved. In this manner, the FAC 31 is bonded after alignment. This means that alignment of the laser emission unit 20 has been completed.

The SAC 32 is an optical component that collimates a slow-axis direction component of the laser beam L having passed through the FAC 31.

The manifold 33 serves as a base material of the semiconductor laser module 10, and is fixed to a housing of a laser machining apparatus. The laser emission unit 20, more specifically, the heat sink 11 is supported and fixed on an upper surface of the manifold 33. Furthermore, the manifold 33 is also a junction member having a water passage for introducing cooling water into the heat sink 11. An example of a material of the manifold 33 is steel use stainless (SUS) 303.

In the Z-axis direction, a Z-direction end portion of the manifold 33 projects forward, that is, projects in a direction in which the laser beam L is emitted, with respect to the laser emission unit 20 on the manifold 33. The SAC 32 is fixed to this end portion with an adhesive 36.

In this example, the SAC 32 is fixed to a Z-axis-direction end surface of the manifold 33 with the adhesive 36 in such a way as to be located on an optical path of the laser beam L emitted from the laser diode element 16 and passing through the FAC 31. With reference to the shape, diameter, and the like of the laser beam L emitted from the laser diode element 16, a position of the SAC 32 is adjusted both in the Y-axis direction and in the Z-axis direction, and an angle of rotation of the SAC 32 around the Z-axis is adjusted. Then, the SAC 32 is fixed to the end surface of the manifold 33 with the adhesive 36 such that the SAC 32 is disposed at the position adjusted both in the Y-axis direction and in the Z-axis direction, and that the adjusted angle of rotation around the Z-axis is achieved. At this time, a surface perpendicular to the Z-axis direction in which the positioning likelihood of the SAC 32 is large is set as a bonding surface. This prevents deterioration of beam quality due to misalignment that occurs in a thickness direction at the time of curing of the adhesive 36. In this manner, the SAC 32 is bonded after alignment. This means that alignment of the semiconductor laser module 10 has been completed.

The manifold 33 has, in a region between the FAC 31 and the SAC 32, a through-hole 331 and a bolt 332. The through-hole 331 penetrates the manifold 33 in the Y-axis direction. The bolt 332 is a fixing member inserted into the through-hole 331. Furthermore, a screw hole into which the bolt 332 is screwed is provided at an installation position of the semiconductor laser module 10 in the housing of the laser machining apparatus (not illustrated). A diameter of the through-hole 331 is set in such a way as to be larger than a diameter of the screw hole and smaller than a diameter of a head of the bolt 332. The through-hole 331 provided in the manifold 33 is aligned with the screw hole provided in the laser machining apparatus, and then, the bolt 332 is inserted into the through-hole 331. Then, the angle of the manifold 33 around the Y-axis is adjusted, and the bolt 332 is screwed into the screw hole. As a result, the manifold 33 is fixed at a predetermined position on the housing of the laser machining apparatus. Note that since the diameter of the through-hole 331 is larger than the diameter of the screw hole, the manifold 33 can be moved in the ZX plane within a range of the diameter of the through-hole 331 in a state where the bolt 332 is loosened. Furthermore, it is also possible to rotate the manifold 33 around the Y-axis.

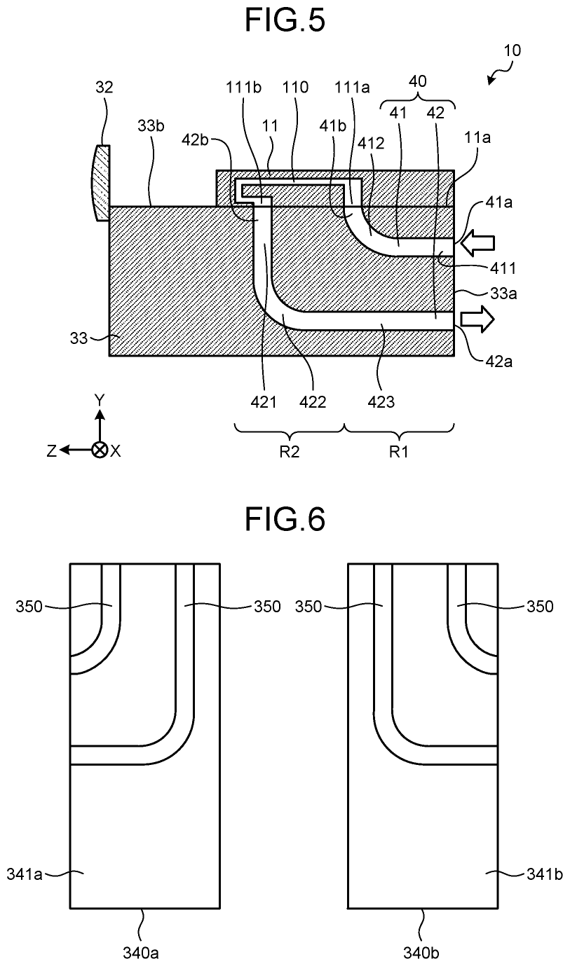

Next, a description will be given of a water passage provided inside the manifold 33 and the heat sink 11, through which cooling water flows. FIG. 4 is a top view of the manifold of the semiconductor laser module according to the first embodiment, which schematically shows an example of a configuration of the manifold. FIG. 5 is a cross-sectional view of the manifold of the semiconductor laser module according to the first embodiment, which schematically shows the example of the configuration of the manifold, and is a cross-sectional view taken along line V-V of FIG. 4. FIG. 4 illustrates the SAC 32 and the manifold 33, and FIG. 5 illustrates the heat sink 11, the SAC 32, and the manifold 33.

The manifold 33 has a water passage 40 therein. The water passage 40 includes a first water passage 41 and a second water passage 42. Cooling water from a cooling water circulation device (not illustrated) flows into the first water passage 41. Cooling water having passed through heat sink 11 returns to the cooling water circulation device through the second water passage 42. The first water passage 41 and the second water passage 42 form a single circulation passage starting from the cooling water circulation device. In one example, the first water passage 41 and the second water passage 42 have annular cross sections perpendicular to directions in which the first water passage 41 and the second water passage 42 extend, respectively.

One end of the first water passage 41 serves as an inlet 41a of cooling water, and another end serves as a connection port 41b for connection with a water passage 110 provided in the heat sink 11. The inlet 41a is provided in a rear surface 33a that is a side surface of the manifold 33, perpendicular to the Z-axis. The connection port 41b is provided in an upper surface 33b that is a side surface of the manifold 33 in contact with the heat sink 11. The rear surface 33a corresponds to a first side surface, and the upper surface 33b corresponds to a second side surface.

The first water passage 41 is provided in an upper portion of a region in the manifold 33, corresponding to the electrode placement region R1. Therefore, the first water passage 41 also has a function of cooling the electrode placement region R1 of the heat sink 11. That is, the first water passage 41 cools heat generated by the laser diode element 16 and transferred via the feed structure 17, the cathode electrode 14, the insulating sheet 13, the anode electrode 12, and the heat sink 11.

One end of the second water passage 42 serves as an outlet 42a of cooling water, and another end serves as a connection port 42b for connection with the water passage 110 provided in the heat sink 11. The outlet 42a is provided in the rear surface 33a of the manifold 33. The connection port 42b is provided in the upper surface 33b of the manifold 33 in contact with the heat sink 11.

The inlet 41a and the outlet 42a are provided in the rear surface 33a of the manifold 33, which is a surface perpendicular to the Z-axis. On the rear surface 33a, the inlet 41a and the outlet 42a are disposed such that the inlet 41a and the outlet 42a have the same X-coordinate and different Y-coordinates. In this example, the inlet 41a is located above the outlet 42a. The inlet 41a and the outlet 42a are connected to the cooling water circulation device by pipes.

The connection ports 41b and 42b are disposed such that the connection ports 41b and 42b have the same X-coordinate and different Z-coordinates on the upper surface 33b of the manifold 33, which is a surface perpendicular to the Y-axis.

The heat sink 11 has the water passage 110 therein. The water passage 110 is provided in such a way as to pass through the element placement region R2 of the heat sink 11. One end of the water passage 110 serves as a connection port 111a which is an inlet of cooling water, and another end serves as a connection port 111b which is an outlet of the cooling water. The connection ports 111a and 111b are provided in a lower surface 11a which is a side surface of the heat sink 11 in contact with the manifold 33. In one example, the water passage 110 has an annular cross section perpendicular to a direction in which the water passage 110 extends. Alignment is performed on the heat sink 11 and the manifold 33 such that the position of the connection port 111a of the heat sink 11 and the position of the connection port 41b of the manifold 33 coincide with each other, and that the position of the connection port 111b of the heat sink 11 and the position of the connection port 42b of the manifold 33 coincide with each other.

FIG. 5 illustrates a cross section of the manifold 33 taken along a plane parallel to the YZ plane passing through the inlet 41a and the outlet 42a. As illustrated in FIG. 5, the water passage 40 has a curved portion with a side surface that is a continuous surface with no corner portion, that is, a surface having a curvature. In the example of FIG. 5, the first water passage 41 includes a straight portion 411 and a curved portion 412, between the inlet 41a and the connection port 41b. The straight portion 411 includes a cylindrical member. The curved portion 412 includes a cylindrical member bent in such a way as to have a curvature along a central axis. Since the curved portion 412 is provided, a Z-axis-direction end portion of the straight portion 411 exists at a position outside a range of a position where the connection port 41b is formed in the Z-axis direction.

The second water passage 42 includes straight portions 421 and 423 and a curved portion 422, between the connection port 42b and the outlet 42a. The straight portions 421 and 423 each include a cylindrical member. The curved portion 422 connects the straight portions 421 and 423. The curved portion 422 includes a cylindrical member bent in such a way as to have a curvature along a central axis. Since the curved portion 422 is provided, a Y-axis-direction end portion of the straight portion 421 exists at a position outside a range of a position where the outlet 42a is formed in the Y-axis direction. Furthermore, a Z-axis-direction end portion of the straight portion 423 exists at a position outside a range of a position where the connection port 42b is formed in the Z-axis direction.

As described above, continuous curved surfaces that are not angular in a direction in which the water passage 40 is formed serve as side surfaces forming the first water passage 41 and the second water passage 42. The curved portions 412 and 422 are desirably gentle from the viewpoint of reducing pressure loss.

Cooling water from the cooling water circulation device flows through the first water passage 41 and the second water passage 42 provided inside the manifold 33 and the water passage 110 provided inside the heat sink 11. As a result, heat generated by the laser diode element 16 and transferred via the submount 15 can be discharged.

Note that a case has been described above in which cooling water from the cooling water circulation device flows into the first water passage 41, passes through the heat sink 11, and flows out through the second water passage 42 to the cooling water circulation device. However, cooling water from the cooling water circulation device may flow into the second water passage 42, pass through the heat sink 11, and flow out through the first water passage 41 to the cooling water circulation device.

A description will be given of a method for manufacturing the above-described manifold 33. FIG. 6 is a diagram schematically showing an example of a method for manufacturing the manifold to be used in the semiconductor laser module according to the first embodiment. First, two plates 340a and 340b are prepared. The plates 340a and 340b are rectangular parallelepiped plates made of a material, such as the SUS 303, serving as a raw material of the manifold 33. The widths of the plates 340a and 340b, which are X-axis-direction lengths, are half the width of the manifold 33. Meanwhile, the heights of the plates 340a and 340b, which are Y-axis-direction lengths, and the depths of the plates 340a and 340b, which are Z-axis-direction lengths, are equal to the height and depth of the manifold 33, respectively. Next, as illustrated in FIG. 6, grooves 350 are formed in side surfaces 341a and 341b of the plates 340a and 340b, which are surfaces perpendicular to the width directions of the plates 340a and 340b respectively. The grooves 350 serve as the first water passage 41 and the second water passage 42. Thereafter, the side surfaces 341a and 341b in which the grooves 350 have been formed are placed in such a way as to face each other, and are joined to each other by brazing. As a result, the manifold 33 described above is manufactured.

Note that this is an example, and the manifold 33 may be manufactured by use of a three-dimensional printer based on three-dimensional data including an internal structure of the manifold 33.

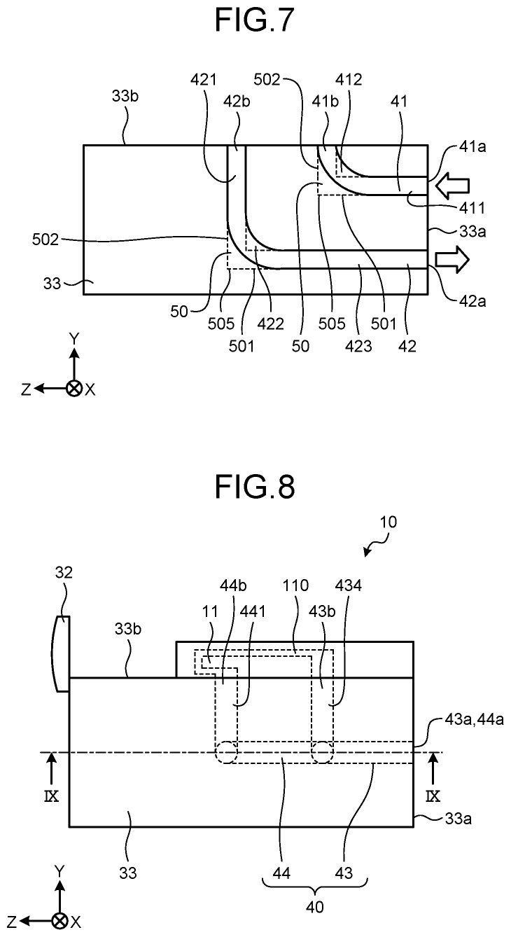

A description will be given of a difference between the water passage 40 of the semiconductor laser module 10 according to the first embodiment and a water passage according to a conventional example disclosed in Patent Literature 1. FIG. 7 is a cross-sectional view of manifolds of semiconductor laser modules of the first embodiment and the conventional example, which schematically illustrates configurations of water passages in the manifolds. Note that since auxiliary lines for description have been drawn, there is no hatched area in FIG. 7.

As indicated by dotted lines in FIG. 7, a water passage 50 according to the conventional example has a configuration in which a straight portion 501 and a straight portion 502 are connected at an intersecting portion. The straight portion 501 includes a cylindrical member extending in the Z-axis direction. The straight portion 502 includes a cylindrical member extending in the Y-axis direction. Since side surfaces of the two straight portions 501 and 502 intersect at a right angle on the YZ plane, a corner portion 505 is generated in a direction in which the water passage 50 is formed. In the water passage 50 in which cooling water is bent at a right angle in this manner, pressure loss increases. Therefore, measures such as increasing the flow velocity of cooling water to be supplied from the cooling water circulation device are taken. As a result, power consumption for cooling increases.

Meanwhile, in the semiconductor laser module 10 according to the first embodiment, the first water passage 41 and the second water passage 42 have the curved portions 412 and 422 with no corner portion, respectively, as described above. Pressure loss is lower at the curved portions 412 and 422 than at corner portions. That is, the structure of the semiconductor laser module 10 according to the first embodiment can reduce pressure loss as compared with the conventional example.

The semiconductor laser module 10 of the first embodiment includes the anode electrode 12 and the insulating sheet 13 on the electrode placement region R1, and includes the submount 15, the laser diode element 16, and the feed structure 17 on the element placement region R2, between the heat sink 11, which has the water passage 110 therein, and the cathode electrode 14. The heat sink 11 is fixed on the manifold 33 having the water passage 40 therein. In the manifold 33, the water passage 40 has the curved portions 412 and 422 with no corner portion. Thus, as compared with the conventional example in which the water passage 50 has the corner portion 505 bent at a right angle, it is possible to reduce pressure loss of cooling water flowing through the water passage 40 in the semiconductor laser module 10 of the first embodiment. As a result, power for causing the cooling water circulation device to operate can be reduced, and power consumption necessary to cool the semiconductor laser module 10 can be reduced as compared with the conventional example.

### Second Embodiment

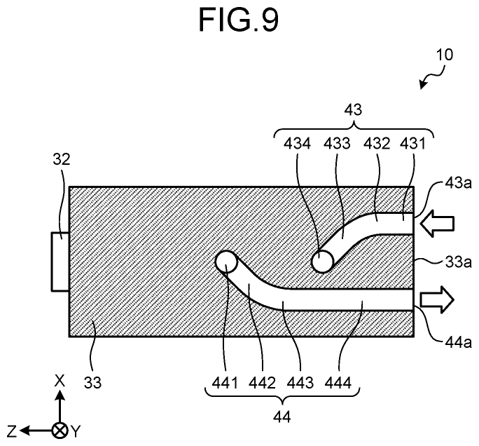

FIG. 8 is a side view of a manifold of a semiconductor laser module according to a second embodiment, which schematically shows an example of a configuration of the manifold. FIG. 9 is a cross-sectional view of the manifold of the semiconductor laser module according to the second embodiment, which schematically shows the example of the configuration of the manifold, and is a cross-sectional view taken along line IX-IX of FIG. 8. FIG. 8 illustrates the heat sink 11, the SAC 32, and the manifold 33, and FIG. 9 illustrates the SAC 32 and the manifold 33. Note that, hereinafter, a difference from the first embodiment will be mainly described.

The water passage 40 provided inside the manifold 33 includes a first water passage 43 and a second water passage 44. Cooling water from a cooling water circulation device (not illustrated) flows into the first water passage 43. Cooling water having passed through heat sink 11 returns to the cooling water circulation device through the second water passage 44. The first water passage 43 and the second water passage 44 form a single circulation passage starting from the cooling water circulation device. In one example, the first water passage 43 and the second water passage 44 have annular cross sections perpendicular to directions in which the first water passage 43 and the second water passage 44 extend, respectively.

One end of the first water passage 43 serves as an inlet 43a of cooling water, and another end serves as a connection port 43b for connection with the water passage 110 provided in the heat sink 11. The inlet 43a is provided in the rear surface 33a of the manifold 33. The connection port 43b is provided in the upper surface 33b of the manifold 33.

The first water passage 43 includes straight portions 431, 433, and 434 and a curved portion 432, between the inlet 43a and the connection port 43b. The straight portions 431, 433, and 434 each include a cylindrical member. The curved portion 432 includes a cylindrical member bent in such a way as to have a curvature along a central axis. The curved portion 432 connects the straight portion 431 and the straight portion 433 with a continuous curved surface having no corner portion. The straight portion 431, the curved portion 432, and the straight portion 433 are provided in the ZX plane. The straight portion 434 extends in the Y-axis direction from an end of the straight portion 433. That is, the first water passage 43 of the second embodiment has a corner portion between the straight portion 433 and the straight portion 434. Meanwhile, the first water passage 43 has no corner portion but has the curved portion 432 in the ZX plane.

One end of the second water passage 44 serves as an outlet 44a of cooling water, and another end serves as a connection port 44b for connection with the water passage 110 provided in the heat sink 11. The outlet 44a is provided in the rear surface 33a of the manifold 33. The connection port 44b is provided in the upper surface 33b of the manifold 33.

The second water passage 44 includes straight portions 441, 442, and 444 and a curved portion 443, between the connection port 44b and the outlet 44a. The straight portions 441, 442, and 444 each include a cylindrical member. The curved portion 443 includes a cylindrical member bent in such a way as to have a curvature along a central axis. The curved portion 443 connects the straight portion 442 and the straight portion 444 with a continuous curved surface having no corner portion. The straight portion 442, the curved portion 443, and the straight portion 444 are provided in the ZX plane. The straight portion 441 extends in the Y-axis direction from an end of the straight portion 442. That is, the second water passage 44 of the second embodiment has a corner portion between the straight portion 441 and the straight portion 442. Meanwhile, the second water passage 44 has no corner portion but has the curved portion 443 in the ZX plane.

As described above, even if the water passage 40 has the corner portion bent at a right angle, it is possible to reduce pressure loss of cooling water flowing through the water passage 40 by providing at least one of the curved portion 432 or 443.

The inlet 43a and the outlet 44a are provided in the rear surface 33a of the manifold 33, which is a surface perpendicular to the Z-axis. The inlet 43a and the outlet 44a are disposed on the rear surface 33a such that the inlet 43a and the outlet 44a have the same Y-coordinate and different X-coordinates. The inlet 43a and the outlet 44a are connected to the cooling water circulation device by pipes. It is possible to prevent an increase in the height of the manifold 33 in the Y-axis direction by disposing the inlet 43a and the outlet 44a at the same level in the Y-axis direction, as compared with the case where the inlet 43a and the outlet 44a are disposed at different levels in the Y-axis direction.

The connection ports 43b and 44b are disposed such that the connection ports 43b and 44b have the same X-coordinate and different Z-coordinates on the upper surface 33b of the manifold 33, which is a surface perpendicular to the Y-axis.

Note that a case has been described above in which cooling water from the cooling water circulation device flows into the first water passage 43, passes through the heat sink 11, and flows out through the second water passage 44 to the cooling water circulation device. However, cooling water from the cooling water circulation device may flow into the second water passage 44, pass through the heat sink 11, and flow out through the first water passage 43 to the cooling water circulation device.

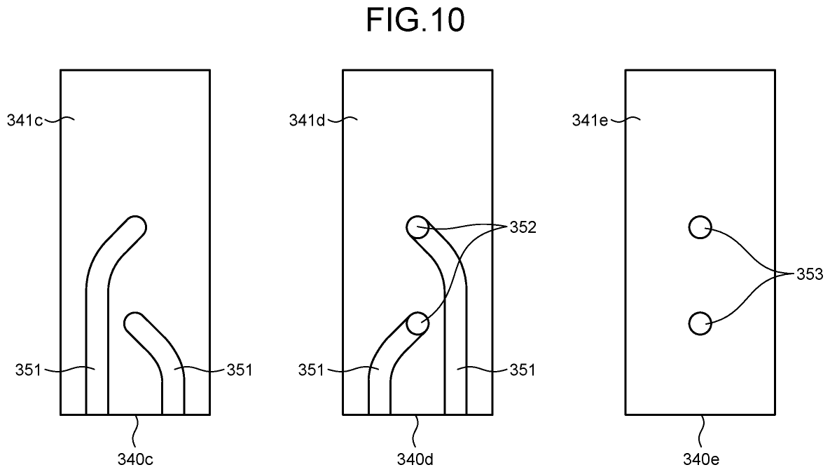

A description will be given of a method for manufacturing the above-described manifold 33. FIG. 10 is a diagram schematically showing an example of a method for manufacturing the manifold to be used in the semiconductor laser module according to the second embodiment. First, three plates 340c, 340d, and 340e are prepared. The plates 340c, 340d, and 340e are rectangular parallelepiped plates made of a material, such as the SUS 303, serving as a raw material of the manifold 33. The X-axis-direction widths and Z-axis-direction depths of the plates 340c, 340d, and 340e are equal to the X-axis-direction width and Z-axis-direction depth of the manifold 33, respectively. Meanwhile, the Y-axis-direction heights of the plates 340c, 340d, and 340e are shorter than the Y-axis-direction height of the manifold 33. When the plates 340c, 340d, and 340e are stacked, the height of the stack of the plates 340c, 340d, and 340e is equal to the height of the manifold 33.

Next, as illustrated in FIG. 10, grooves 351 are formed in a side surface 341c of the plate 340c, which is a surface perpendicular to the height direction. The grooves 351 serve as the first water passage 43 and the second water passage 44. The grooves 351 and through-holes 352 are formed in a side surface 341d of the plate 340d, which is a surface perpendicular to the height direction. The grooves 351 serve as the first water passage 43 and the second water passage 44. The through-holes 352 penetrate the plate 340d in a thickness direction at ends of the grooves 351. Through-holes 353 penetrating the plate 340e in the thickness direction are formed in a side surface 341e of the plate 340e, which is a surface perpendicular to the height direction. The through-holes 353 are provided in such a way as to correspond to the positions of the through-holes 352.

Thereafter, the side surface 341c of the plate 340c and the side surface 341d of the plate 340d in which the grooves 351 have been formed are placed in such a way as to face each other, and are joined to each other by brazing. Furthermore, the plate 340e is disposed on a surface of the plate 340d opposite to a surface brazed to the plate 340c, such that the through-holes 352 and the through-holes 353 are aligned. Then, the plate 340e is joined to the plate 340d by brazing. Thus, the above-described manifold 33 is manufactured. Note that, also in this case, the manifold 33 may be manufactured by a three-dimensional printer.

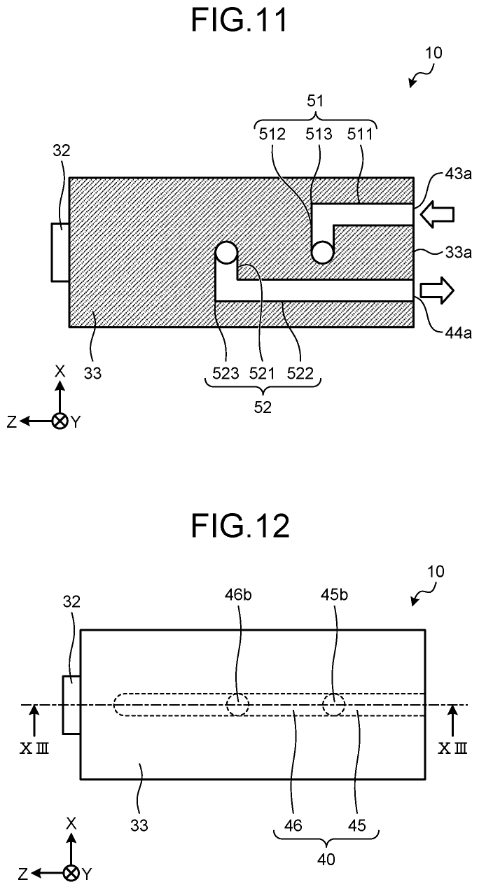

A description will be given of a difference between the water passage 40 of the semiconductor laser module 10 according to the second embodiment and a water passage according to a conventional example disclosed in Patent Literature 1. FIG. 11 is a cross-sectional view of the manifold of the semiconductor laser module, which shows a conventional example of a water passage in the manifold. FIG. 11 corresponds to a cross-sectional view taken along line IX-IX of FIG. 8. In a case where a water passage is formed in the manifold 33 by application of the technique described in Patent Literature 1, a first water passage 51 extending from the inlet 43a to a position corresponding to a position where the connection port 43b is formed includes a straight portion 511 and a straight portion 512. The straight portion 511 includes a cylindrical member extending in the Z-axis direction. The straight portion 512 includes a cylindrical member extending in the X-axis direction. A corner portion 513 is formed at a connecting part for connection between the two straight portions 511 and 512. In addition, a second water passage 52 extending from a position corresponding to a position where the connection port 44b is formed to the outlet 44a includes a straight portion 521 and a straight portion 522. The straight portion 521 includes a cylindrical member extending in the X-axis direction. The straight portion 522 includes a cylindrical member extending in the Z-axis direction. A corner portion 523 is formed at a connecting part for connection between the two straight portions 521 and 522.

In the conventional example, a part of the first water passage 51, which connects positions corresponding to the inlet 43a and the connection port 43b on the ZX plane, is formed as the corner portion 513 bent at a right angle, and a part of the second water passage 52, which connects positions corresponding to the outlet 44a and the connection port 44b, is formed as the corner portion 523 bent at a right angle, as illustrated in FIG. 11. As described above, pressure loss increases at the corner portions 513 and 523. Therefore, measures such as increasing the flow velocity of cooling water to be supplied from the cooling water circulation device are taken. Meanwhile, in the manifold 33 of the semiconductor laser module 10 according to the second embodiment illustrated in FIG. 9, the water passage 40 has the curved portions 432 and 443 in the ZX plane, instead of the corner portions 513 and 523. At the curved portions 432 and 443, pressure loss is reduced as compared with the case of the corner portions 513 and 523. As a result, the flow velocity of cooling water to be supplied from the cooling water circulation device need not be increased as compared with the conventional example.

Note that, in the semiconductor laser module 10 according to the second embodiment, a single corner portion exists between a part of the first water passage 43 provided in the ZX plane and the straight portion 434 extending in the Y-axis direction, and a single corner portion exists between a part of the second water passage 44 provided in the ZX plane and the straight portion 441 extending in the Y-axis direction. However, these corner portions are also provided in the conventional example, and the number of corner portions of the entire first water passage 43 and the entire second water passage 44 can be reduced in the ZX plane as compared with the conventional example. Thus, pressure loss can be reduced as compared with the conventional technique. As described above, the water passage 40 is formed in the manifold 33 such that the water passage 40 has the curved portions 432 and 443 instead of the corner portions 513 and 523. As a result, pressure loss can be reduced as compared with the conventional technique.

In the manifold 33 of the semiconductor laser module 10 according to the second embodiment, the water passage 40 has the curved portions 432 and 443 in the ZX plane. This achieves the effect of enabling pressure loss of cooling water flowing inside to be reduced as compared with a case where a corner portion is provided in the water passage 40 in the ZX plane.

Furthermore, in the manifold 33 of the semiconductor laser module 10 according to the second embodiment, the inlet 43a of the first water passage 43 and the outlet 44a of the second water passage 44 are provided in the rear surface 33a of the manifold 33 such that the inlet 43a and the outlet 44a are located at the same level in the Y-axis direction. As a result, the height of the manifold 33 in the Y-axis direction can be reduced as compared with a case where the inlet 43a and the outlet 44a are provided at different levels in the Y-axis direction. That is, the effect of enabling the semiconductor laser module 10 to be reduced in size in the height direction is achieved. Furthermore, the second embodiment achieves the effect of enabling the element placement region R2 and the electrode placement region R1 to be cooled by the single circulation passage connected to the cooling water circulation device, that is, the circulation passage including the first water passage 43 and the second water passage 44, without providing one circulation passage connected to a cooling water circulation device for cooling the element placement region R2 and one circulation passage connected to a cooling water circulation device for cooling the electrode placement region R1.

### Third Embodiment

As illustrated in FIGS. 1 and 2, the SAC 32 is fixed to a front end portion of the manifold 33 in the Z-axis direction. The SAC 32 generates heat because the SAC 32 is irradiated with the laser beam L emitted from the laser diode element 16. In a third embodiment, a configuration of the semiconductor laser module 10 capable of cooling the SAC 32 will be described. However, since the basic configuration of the semiconductor laser module 10 is similar to the configuration described in the first embodiment with reference to FIGS. 1 to 3, description thereof will be omitted, and different portions will be described below.

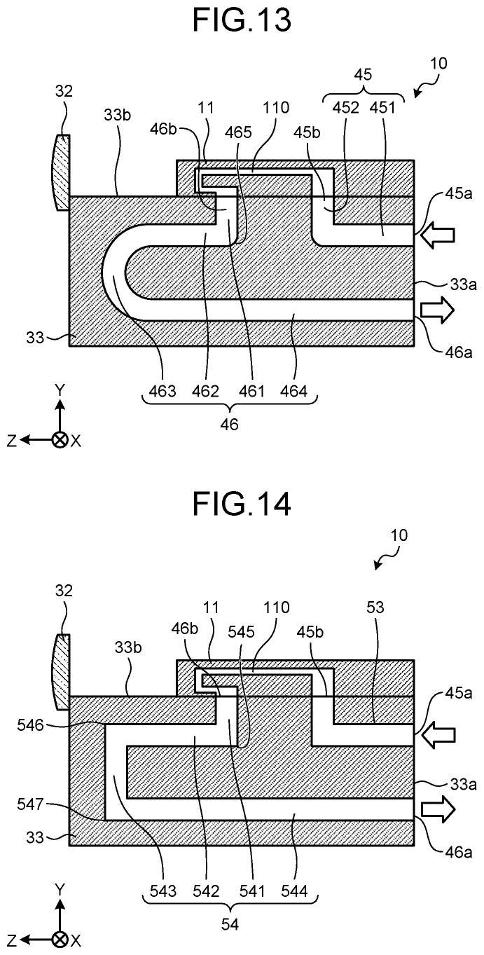

FIG. 12 is a top view of a manifold of a semiconductor laser module according to the third embodiment, which schematically shows an example of a configuration of the manifold. FIG. 13 is a cross-sectional view of the manifold of the semiconductor laser module according to the third embodiment, which schematically shows the example of the configuration of the manifold, and is a cross-sectional view taken along line XIII-XIII of FIG. 12. FIG. 12 illustrates the SAC 32 and the manifold 33, and FIG. 13 illustrates the heat sink 11, the SAC 32, and the manifold 33.

The manifold 33 has a water passage 40 therein. The water passage 40 includes a first water passage 45 and a second water passage 46. Cooling water from a cooling water circulation device (not illustrated) flows into the first water passage 45. Cooling water having passed through heat sink 11 returns to the cooling water circulation device through the second water passage 46. The first water passage 45 and the second water passage 46 form a single circulation passage starting from the cooling water circulation device. In one example, the first water passage 45 and the second water passage 46 have annular cross sections perpendicular to directions in which the first water passage 45 and the second water passage 46 extend, respectively.

One end of the first water passage 45 serves as an inlet 45a of cooling water, and another end serves as a connection port 45b for connection with the water passage 110 provided in the heat sink 11. The inlet 45a is provided in the rear surface 33a of the manifold 33. The connection port 45b is provided in the upper surface 33b of the manifold 33.

The first water passage 45 includes straight portions 451 and 452 between the inlet 45a and the connection port 45b. The straight portions 451 and 452 each include a cylindrical member. The straight portion 451 extends in the Z-axis direction, and the straight portion 452 extends in the Y-axis direction from one end of the straight portion 451. That is, the first water passage 45 of the third embodiment has a corner portion between the straight portion 451 and the straight portion 452.

One end of the second water passage 46 serves as an outlet 46a of cooling water, and another end serves as a connection port 46b for connection with the water passage 110 provided in the heat sink 11. The outlet 46a is provided in the rear surface 33a of the manifold 33. The connection port 46b is provided in the upper surface 33b of the manifold 33.

The second water passage 46 includes straight portions 461, 462, and 464 and a curved portion 463, between the connection port 46b and the outlet 46a. The straight portions 461, 462, and 464 each include a cylindrical member. The curved portion 463 includes a cylindrical member bent in such a way as to have a curvature along a central axis. The curved portion 463 connects the straight portion 462 and the straight portion 464 with a continuous curved surface having no corner portion. The first water passage 45 and the second water passage 46 are provided in the YZ plane. The second water passage 46 of the third embodiment has a single corner portion 465 at which the straight portion 461 and the straight portion 462 are connected at a right angle. Meanwhile, not a corner portion but the curved portion 463 exists in the rest of the second water passage 46.

Furthermore, the second water passage 46 is configured as follows. The straight portion 462 is provided toward a Z-axis positive side end surface of the manifold 33, that is, an end surface on which the SAC 32 is fixed. The direction of the second water passage 46 is changed to the negative direction side of the Z-axis at the curved portion 463, to reach the outlet 46a through the straight portion 464 disposed below the straight portion 462. That is, since the curved portion 463 is located in a region on the SAC 32 side with respect to the front surface of the heat sink 11, the second water passage 46 is configured in such a way as to pass through the front surface of the manifold 33 to which the SAC 32 is fixed.

With such a configuration, the manifold 33 between the heat sink 11 and the SAC 32 is also cooled by circulation of cooling water, and part of heat generated by the SAC 32 is discharged through the manifold 33 and the cooling water.

Note that a case has been described above in which cooling water from the cooling water circulation device flows into the first water passage 45, passes through the heat sink 11, and flows out through the second water passage 46 to the cooling water circulation device. However, cooling water from the cooling water circulation device may flow into the second water passage 46, pass through the heat sink 11, and flow out through the first water passage 45 to the cooling water circulation device. Furthermore, the method for manufacturing the manifold 33 of the semiconductor laser module 10 according to the third embodiment is similar to the method described in the first embodiment, and thus description thereof will be omitted.

A description will be given of a difference between the water passage 40 of the semiconductor laser module 10 according to the third embodiment and a water passage according to a conventional example disclosed in Patent Literature 1. FIG. 14 is a cross-sectional view of the manifold of the semiconductor laser module, which shows a conventional example of a water passage in the manifold. FIG. 14 corresponds to a cross-sectional view taken along line XIII-XIII of FIG. 12. The manifold 33 includes a first water passage 53 and a second water passage 54 therein. However, since the first water passage 53 has the same configuration as the first water passage 45 in FIG. 13, description thereof will be omitted, and the second water passage 54 will be described.

In a case where the second water passage 54 is formed in the manifold 33 by application of the technique described in Patent Literature 1, the second water passage 54 extending from the connection port 46b to the outlet 46a includes a straight portion 541, a straight portion 542, a straight portion 543, and a straight portion 544. The straight portion 541 extends in the Y-axis direction. The straight portion 542 extends in the Z-axis direction. The straight portion 543 extends in the Y-axis direction. The straight portion 544 extends in the Z-axis direction. A corner portion 545 is formed at a connecting part between the straight portion 541 and the straight portion 542. A corner portion 546 is formed at a connecting part between the straight portion 542 and the straight portion 543. A corner portion 547 is formed at a connecting part between the straight portion 543 and the straight portion 544.

In the conventional example, the second water passage 54 connecting the connection port 46b and the outlet 46a in the YZ plane has the corner portions 545, 546, and 547 bent at right angles, as illustrated in FIG. 14. As described above, pressure loss increases at the corner portions 545, 546, and 547. Therefore, measures such as increasing the flow velocity of cooling water to be supplied from the cooling water circulation device are taken. Meanwhile, in the manifold 33 of the semiconductor laser module 10 according to the third embodiment illustrated in FIG. 13, the single corner portion 465 exists at a connecting part between the straight portion 461 and the straight portion 462 of the second water passage 46 in the YZ plane. However, the curved portion 463 exists instead of the corner portions 546 and 547 in the rest of the second water passage 46. Pressure loss is reduced at the curved portion 463 as compared with the case of the corner portions 546 and 547.

In the manifold 33 of the semiconductor laser module 10 according to the third embodiment, the second water passage 46 has the curved portion 463 between the connection port 46b and the outlet 46a. As a result, the second water passage 46 has the effect of reducing pressure loss of cooling water flowing inside as compared with a case where the water passage has a corner portion.

Furthermore, in the manifold 33 of the semiconductor laser module 10 according to the third embodiment, the second water passage 46 extends from the connection port 46b, and passes through the SAC 32-side end portion of the manifold 33. This achieves the effect of enabling heat generated by the SAC 32 to be discharged through the manifold 33 and cooling water.

### Fourth Embodiment

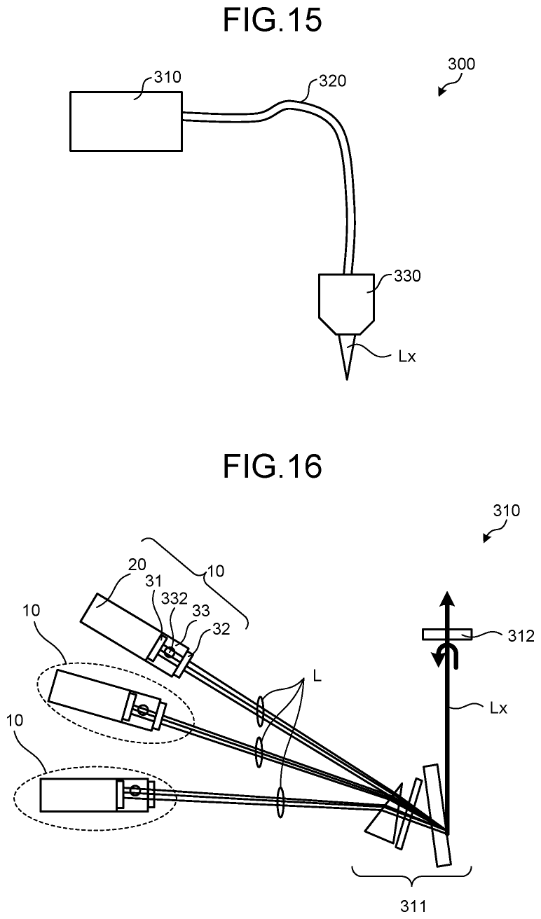

The semiconductor laser module 10 described in the first to third embodiments can be used as a light source of a laser beam for a laser machining apparatus. FIG. 15 is a diagram schematically showing an example of a configuration of a laser machining apparatus according to a fourth embodiment. A laser machining apparatus 300 includes a laser oscillator 310, an optical fiber 320, and a machining head 330.

The laser oscillator 310 emits a laser beam Lx. FIG. 16 is a diagram schematically showing an example of a configuration of the laser oscillator to be used in the laser machining apparatus according to the fourth embodiment. The laser oscillator 310 includes a plurality of the semiconductor laser modules 10, an optical coupler 311, and an external resonator mirror 312. As described above, the semiconductor laser module 10 has the following structure. The FAC 31 is bonded to the laser emission unit 20, and the laser emission unit 20 is fixed to the manifold 33. Then, the SAC 32 is fixed to the manifold 33. The optical coupler 311 couples the laser beams L from the plurality of semiconductor laser modules 10. A prism, a diffraction grating, or the like is used as the optical coupler 311. The external resonator mirror 312 transmits part of the laser beam Lx coupled by the optical coupler 311, and reflects the remaining part toward the semiconductor laser module 10. The external resonator mirror 312 forms an optical resonator, together with an emission surface of the laser diode element 16 of the semiconductor laser module 10, from which the laser beam L is emitted.

Returning to FIG. 15, the optical fiber 320 transmits, to the machining head 330, the coupled laser beam Lx emitted from the laser oscillator 310.

The machining head 330 condenses the laser beam Lx transmitted through the optical fiber 320, and irradiates a workpiece with the laser beam Lx. The machining head 330 includes a condensing optical system that condenses the laser beam Lx transmitted through the optical fiber 320 and irradiates the workpiece with the laser beam Lx. At the time of machining, the machining head 330 is disposed in such a way as to face a portion of the workpiece to be machined.

As illustrated in FIG. 16, the laser oscillator 310 includes the plurality of semiconductor laser modules 10. As described above, the FAC 31 and the SAC 32 are integrated with the laser emission unit 20 including the laser diode element 16 in each semiconductor laser module 10. In each semiconductor laser module 10, the bolt 332 is loosened, and the manifold 33 is rotated around the position of the bolt 332 to perform alignment. Then, this alignment process is performed separately for each semiconductor laser module 10 provided in the laser oscillator 310.

Note that, in the above description, when the p-type semiconductor element and n-type semiconductor element of the laser diode element 16 are disposed in reverse, the anode electrode 12 and the cathode electrode 14 are replaced with each other. In this case, the cathode electrode corresponds to the first electrode, and the anode electrode corresponds to the second electrode.

The configurations set forth in the above embodiments show examples, and it is possible to combine the configurations with another known technique or combine the embodiments with each other, and is also possible to partially omit or change the configurations without departing from the scope of the present disclosure.

### REFERENCE SIGNS LIST

10 semiconductor laser module; 11 heat sink; 11a lower surface; 12 anode electrode; 13 insulating sheet; 14 cathode electrode; 15 submount; 16 laser diode element; 17 feed structure; 20 laser emission unit; 31 FAC; 32 SAC; 33 manifold; 33a rear surface; 33b upper surface; 35, 36 adhesive; 40, 50, 110 water passage; 41, 43, 45, 51, 53 first water passage; 41a, 43a, 45a inlet; 41b, 42b, 43b, 44b, 45b, 46b, 111a, 111b connection port; 42, 44, 46, 52, 54 second water passage; 42a, 44a, 46a outlet; 121 first portion; 122 second portion; 300 laser machining apparatus; 310 laser oscillator; 311 optical coupler; 312 external resonator mirror; 320 optical fiber; 330 machining head; 331, 352, 353 through-hole; 332 bolt; 340a, 340b, 340c, 340d, 340e plate; 350, 351 groove; 411, 421, 423, 431, 433, 434, 441, 442, 444, 451, 452, 461, 462, 464, 501, 502, 511, 512, 521, 522, 541, 542, 543, 544 straight portion; 412, 422, 432, 443, 463 curved portion; 465, 505, 513, 523, 545, 546, 547 corner portion; L, Lx laser beam; R1 electrode placement region; R2 element placement region.

1. A semiconductor laser module comprising:
a manifold having a water passage through which cooling water can flow, the water passage being provided inside the manifold;
a heat sink disposed on the manifold, the heat sink allowing the cooling water to circulate through the water passage of the manifold and the heat sink;
a first electrode disposed in a first region of the heat sink;
an insulating layer disposed on the first electrode;
a submount disposed in a second region of the heat sink, the second region being different from the first region, the submount being electrically and thermally conductive;
a laser diode element disposed on the submount, the laser diode element emitting a laser beam;
a feed structure disposed on the laser diode element, the feed structure being electrically and thermally conductive;
a second electrode provided on the insulating layer and the feed structure such that the second electrode is in contact with the insulating layer and the feed structure; and
an optical component fixed to an end portion of the manifold, the end portion being on a laser beam emission side, wherein
the manifold projects out with respect to an end surface of the heat sink, the end surface being on the laser beam emission side,
the water passage of the manifold includes a first water passage and a second water passage, the first water passage connecting an inlet and a first connection port, the inlet being provided in a first side surface of the manifold, the first connection port being provided in a second side surface in contact with the heat sink, the second water passage connecting a second connection port and an outlet, the second connection port being provided in the second side surface, the outlet being provided in the first side surface,
the first water passage or the second water passage passes through a region from an end portion of the heat sink to the end portion of the manifold, the end portion of the heat sink and the end portion of the manifold being on the laser beam emission side, and has a curved portion in the manifold, the curved portion including a continuous curved surface with no corner portion.

2.-3. (canceled)

4. The semiconductor laser module according to claim 1, wherein the inlet and the outlet are provided in the first side surface at different levels in a direction in which the first electrode, the insulating layer, and the second electrode are stacked.

5. A laser machining apparatus comprising:
a laser oscillator including a plurality of the semiconductor laser modules according to claim 1, the laser oscillator coupling the laser beams emitted from the plurality of semiconductor laser modules and emitting the coupled laser beams;
an optical fiber to transmit the coupled laser beams emitted from the laser oscillator; and
a machining head to condense the coupled laser beams transmitted through the optical fiber and irradiate a workpiece with the coupled laser beams.

6. A laser machining apparatus comprising:
a laser oscillator including a plurality of the semiconductor laser modules according to claim 4, the laser oscillator coupling the laser beams emitted from the plurality of semiconductor laser modules and emitting the coupled laser beams;
an optical fiber to transmit the coupled laser beams emitted from the laser oscillator; and
a machining head to condense the coupled laser beams transmitted through the optical fiber and irradiate a workpiece with the coupled laser beams.
